(19) United States
(12) Patent Application Publication
(10) Pub. No.: US 2024/0164106 A1
(43) Pub. Date: May 16, 2024

(54) SEMICONDUCTOR DEVICES HAVING GATE ELECTRODES WITH RING-SHAPED SEGMENTS THEREIN

(71) Applicant: Samsung Electronics Co., Ltd., Suwon-si (KR)

(72) Inventors: Dong Jin Lee, Suwon-si (KR); Jun Hee Lim, Suwon-si (KR); Kang-Oh Yun, Suwon-si (KR)

(21) Appl. No.: 18/465,405

(22) Filed: Sep. 12, 2023

(30) Foreign Application Priority Data
Nov. 15, 2022 (KR) 10-2022-0152236

(51) Int. Cl. H10B 43/40; H10B 43/10

(52) U.S. Cl. CPC H10B 43/40; H10B 43/10; H10B 43/27

(57) ABSTRACT

A semiconductor device is provided. The semiconductor device includes an active region, a first source/drain region disposed on the active region, a first contact on the first source/drain region, a second source/drain region spaced apart from the first source/drain region and disposed on the active region, a second contact on the second source/drain region and a first gate electrode disposed on the active region. The first gate electrode includes a first ring portion, which surrounds the first contact, but the second contact extends outside the first ring portion.

### REFERENCE TO PRIORITY APPLICATION

This application claims priority to Korean Patent Application No. 10-2022-0152236, filed Nov. 15, 2022, the disclosure of which is hereby incorporated herein by reference.

### BACKGROUND

The present disclosure relates to semiconductor devices that are suitable for use in integrated circuits.

A semiconductor device having an enhanced degree of integration has been required to fulfil excellent performance and low cost, which are required by consumers. In case of the semiconductor device, since the degree of integration is an important factor that determines the price of a product, an enhanced degree of integration has been especially required.

In case of a two-dimensional or planar semiconductor device, since the degree of integration is mainly determined by an area occupied by a unit memory cell, it is greatly affected by the level of the technology for forming a fine pattern. However, since ultra-high-priced equipment is required for the fine pattern, the degree of integration of the two-dimensional semiconductor device is increasing but is still restrictive. Therefore, three-dimensional semiconductor devices including memory cells arranged in a three-dimension have been proposed.

### SUMMARY

An object of the present disclosure is to provide a semiconductor device in which reliability of a product is improved.

According to some aspects of the present inventive concept, there is provided a semiconductor device including an active region, a first source/drain region disposed on the active region, a first contact on the first source/drain region, a second source/drain region spaced apart from the first source/drain region and disposed on the active region, a second contact on the second source/drain region and a first gate electrode disposed on the active region. The first gate electrode includes a first ring portion surrounding the first contact, whereas the second contact extends external to the first ring portion.

According to some aspects of the present inventive concept, there is provided a semiconductor device including: (i) a first active pattern extending in a first direction, (ii) a second active pattern extending adjacent to the first active pattern in a second direction crossing the first direction and extended in the first direction, (iii) a device isolation layer adjacent to the first active pattern in the second direction, adjacent to the second active pattern in the first direction and extended in the first direction, (iv) a first source/drain region disposed on the first active pattern, (v) a second source/drain region disposed on the first active pattern and spaced apart from the first source/drain region in the first direction, (vi) a third source/drain region disposed on the second active pattern and spaced apart from the first source/drain region and the second source/drain region, (vii) a first contact on the first source/drain region, (viii) a second contact on the second source/drain region, (ix) a third contact on the third source/drain region, and (x) a first gate electrode that extends over the first active pattern and the second active pattern, and includes a first ring portion surrounding the third contact. In some embodiments, the first source/drain region and the second source/drain region are disposed outside the first ring portion, and the third contact is spaced apart from the first contact in a third direction crossing the first direction and the second direction and is spaced apart from the second contact in a fourth direction crossing the first direction, the second direction and the third direction.

According to some additional aspects of the present inventive concept, there is provided a semiconductor device including a memory cell region, a plurality of bit lines connected to a plurality of memory cells in the cell region, and a peripheral region including a page buffer connected to the plurality of bit lines. The page buffer includes an active pattern, a first source/drain region disposed on the active pattern, a second source/drain region spaced apart from the first source/drain region in a first direction and disposed on the active pattern, a third source/drain region spaced apart from the first source/drain region in a second direction crossing the first direction and disposed on the active pattern, a fourth source/drain region spaced apart from the first source/drain region in a third direction crossing the first direction and the second direction and disposed on the active pattern, a first contact on the first source/drain region, a second contact on the second source/drain region, a third contact on the third source/drain region, a fourth contact on the fourth source/drain region and a first gate electrode disposed on the active pattern. The first gate electrode includes a ring portion surrounding the fourth contact. The first source/drain region, the second source/drain region, the third source/drain region, the first contact, the second contact and the third contact are disposed outside the ring portion, and the first gate electrode further includes an extension portion extended between the first contact and the second contact.

The objects of the present disclosure are not limited to those mentioned above and additional objects of the present disclosure, which are not mentioned herein, will be clearly understood by those skilled in the art from the following description of the present disclosure.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exemplary block diagram illustrating a semiconductor device according to some embodiments.

FIG. 2 is an exemplary circuit view illustrating a semiconductor device according to some embodiments.

FIG. 3 is a layout view illustrating a semiconductor device according to some embodiments.

FIG. 4 is an enlarged view illustrating a region P of FIG. 3.

FIG. 5 is a cross-sectional view taken along line A-A of FIG. 3.

FIG. 6 is a cross-sectional view taken along line B-B of FIG. 3.

FIG. 7 is a cross-sectional view taken along line C-C of FIG. 3.

FIG. 8 is a cross-sectional view taken along line D-D of FIG. 3.

FIG. 9 is a cross-sectional view taken along line E-E of FIG. 3.

FIG. 10 is a layout view illustrating a semiconductor device according to some other embodiments.

FIG. 11 is a cross-sectional view taken along line B-B of FIG. 10.

FIG. 12 is a layout view illustrating a semiconductor device according to some other embodiments.

FIG. 13 is a cross-sectional view taken along line B-B of FIG. 12.

FIG. 14 is a layout view illustrating a semiconductor device according to some other embodiments.

FIG. 15 is a cross-sectional view illustrating a semiconductor device according to some embodiments.

FIG. 16 is an enlarged view illustrating a region R1 of FIG. 15.

FIG. 17 is a cross-sectional view illustrating a semiconductor device according to some other embodiments.

FIG. 18 is an enlarged view illustrating a region R1 of FIG. 17.

FIG. 19 is an exemplary block diagram illustrating an electronic system according to some embodiments.

FIG. 20 is an exemplary perspective view illustrating an electronic system according to some embodiments.

FIG. 21 is a schematic cross-sectional view taken along line I-I of FIG. 20.

### DETAILED DESCRIPTION OF THE DISCLOSURE

Hereinafter, embodiments according to the technical spirits of the present disclosure will be described with reference to the accompanying drawings.

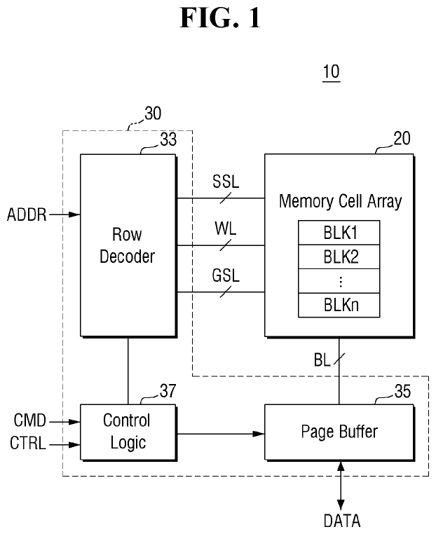

FIG. 1 is an exemplary block diagram illustrating a semiconductor device according to some embodiments. Referring to FIG. 1, a semiconductor device 10 according to some embodiments includes a memory cell array 20 and a peripheral circuit 30. As shown, the memory cell array 20 may include a plurality of memory cell blocks BLK1 to BLKn, and each of the memory cell blocks BLK1 to BLKn may include a plurality of memory cells. The memory cell array 20 may be connected to the peripheral circuit 30 through bit lines BL, word lines WL, string selection lines SSL and ground selection lines GSL. In detail, the memory cell blocks BLK1 to BLKn may be connected to a row decoder 33 through the word lines WL, the string selection lines SSL and the ground selection lines GSL. Also, the memory cell blocks BLK1 to BLKn may be connected to a page buffer 35 through the bit lines BL.

The peripheral circuit 30 may receive an address ADDR, a command CMD and a control signal CTRL from external the semiconductor device 10, and may transmit and receive data to and from an external device of the semiconductor device 10. The peripheral circuit 30 may include a row decoder 33, a page buffer 35 and control logic 37. Although not shown, the peripheral circuit 30 may further include various sub-circuits such as an input/output circuit, a voltage generation circuit for generating various voltages required for an operation of the semiconductor device 10 and an error correction circuit for correcting an error of the data DATA read from the memory cell array 20.

The control logic 37 may be connected to the row decoder 33 and the page buffer 35. Although not shown, the control logic 37 may be connected to the input/output circuit and the voltage generation circuit. The control logic 37 may control an overall operation of the semiconductor device 10. The control logic 37 may generate various internal control signals used in the semiconductor device 10 in response to the control signal CTRL. For example, when a memory operation such as a program operation or an erase operation is performed, the control logic 37 may adjust a voltage level provided to the word line WL and the bit line BL.

The row decoder 33 may select at least one of the plurality of memory cell blocks BLK1 to BLKn in response to the address ADDR, and may select at least one word line WL, at least one string selection line SSL and at least one ground selection line GSL of the selected memory cell blocks BLK1 to BLKn. Also, the row decoder 33 may transfer a voltage for performing the memory operation to the word line WL of the selected memory cell blocks BLK1 to BLKn.

The page buffer 35 may be connected to the memory cell array 20 through the bit lines BL. The page buffer 35 may operate as a write driver or a sense amplifier. In detail, when the program operation is performed, the page buffer 35 may operate as the write driver to apply a voltage according to the data DATA to be stored in the memory cell array 20 to the bit lines BL. When a read operation is performed, the page buffer 35 may operate as the sense amplifier to sense the data DATA stored in the memory cell array 20.

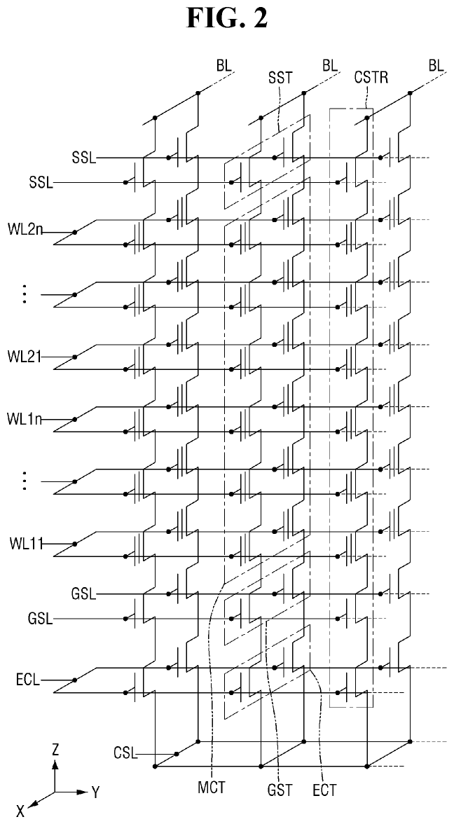

FIG. 2 is an exemplary circuit view illustrating a semiconductor device according to some embodiments. Referring to FIG. 2, a memory cell array (e.g., 20 of FIG. 1) of the semiconductor device according to some embodiments includes a common source line CSL, a plurality of bit lines BL and a plurality of cell strings CSTR. As shown, the common source line CSL may be extended in a first direction X. In some embodiments, a plurality of common source lines CSL may be two-dimensionally arranged. For example, the plurality of common source lines CSL may be spaced apart from each other and thus extended in the first direction X. The electrically equivalent voltage may be applied to the common source lines CSL, or different voltages may be applied to the common source lines CSL so that the common source lines may be separately controlled.

The plurality of bit lines BL may be two-dimensionally arranged. For example, the bit lines BL may be spaced apart from each other and thus extended in a second direction Y crossing the first direction X. The plurality of cell strings CSTR may be connected to the respective bit lines BL in parallel. The cell strings CSTR may be commonly connected to the common source line CSL. That is, the plurality of cell strings CSTR may be disposed between the bit lines BL and the common source line CSL. Each of the cell strings CSTR may include a ground selection transistor GST connected to the common source line CSL, a string selection transistor SST connected to the bit line BL and a plurality of memory cell transistors MCT disposed between the ground selection transistor GST and the string selection transistor SST. Each of the memory cell transistors MCT may include a data storage element. The ground selection transistor GST, the string selection transistor SST and the memory cell transistors MCT may be connected in series.

The common source line CSL may be commonly connected to sources of the ground selection transistors GST. The ground selection line GSL, a plurality of word lines WL11 to WL1n and WL21 to WL2n and the string selection line SSL may be disposed between the common source line CSL and the bit line BL. The ground selection line GSL may be used as a gate electrode of the ground selection transistor GST, the word lines WL11 to WL1n and WL21 to WL2n may be used as gate electrodes of the memory cell transistors MCT, and the string selection line SSL may be used as a gate electrode of the string selection transistor SST.

In some embodiments, erase control transistors ECT may be disposed between the common source line CSL and the ground selection transistor GST. The common source line CSL may be commonly connected to sources of the erase control transistors ECT. An erase control line ECL may be disposed between the common source line CSL and the ground selection line GSL. The erase control line ECL may be used as a gate electrode of the erase control transistor ECT. The erase control transistor ECT may perform an erase operation of the memory cell array by generating a gate induced drain leakage (GIDL).

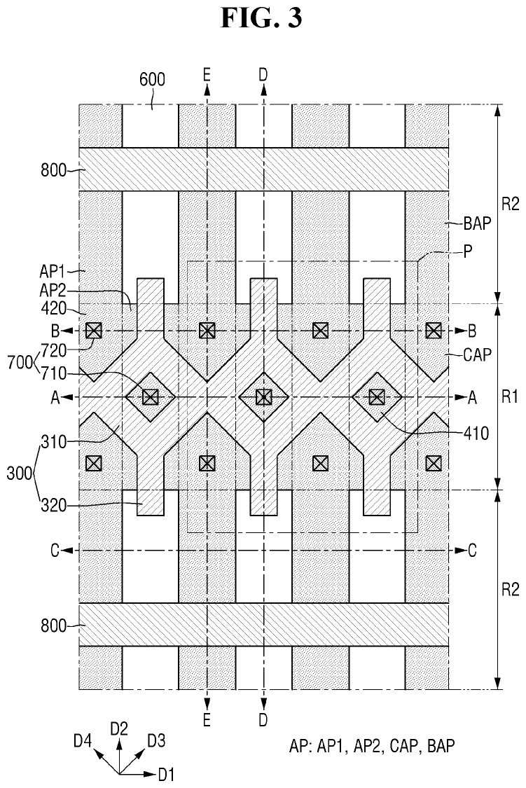

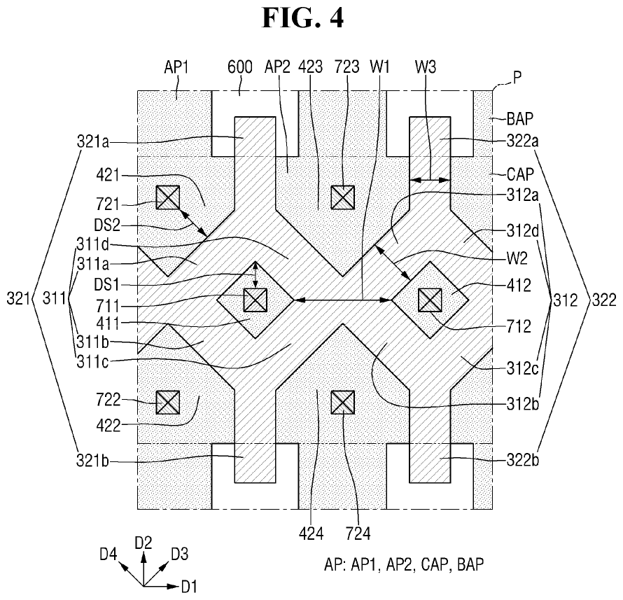

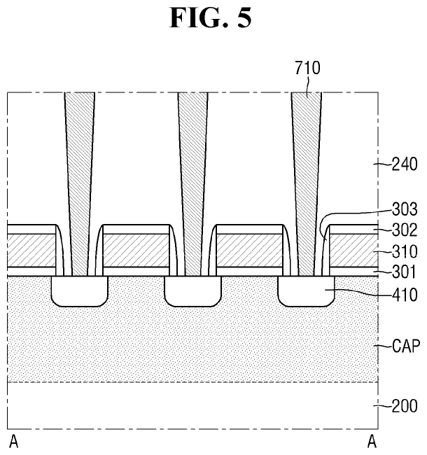

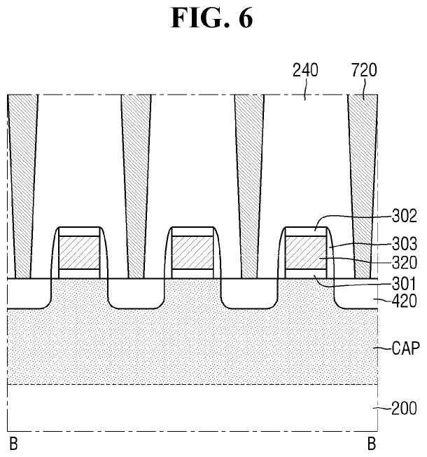

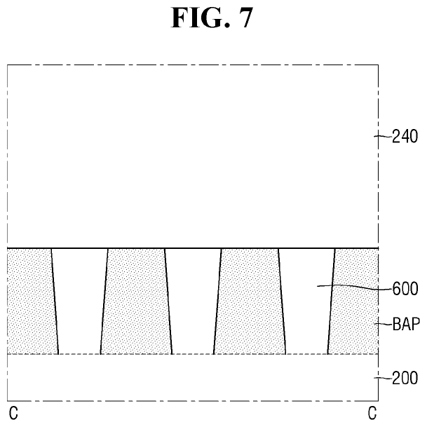

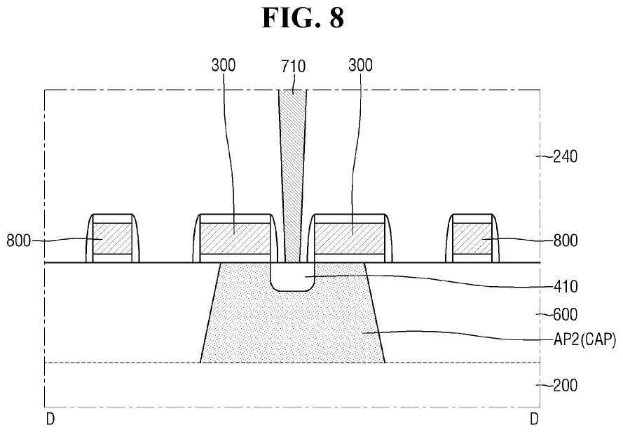

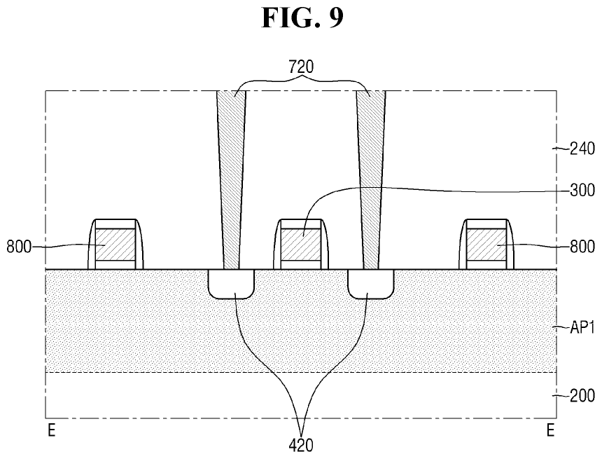

FIG. 3 is a layout view illustrating a semiconductor device according to some embodiments. FIG. 4 is an enlarged view illustrating a region P of FIG. 3; FIG. 5 is a cross-sectional view taken along line A-A of FIG. 3; FIG. 6 is a cross-sectional view taken along line B-B of FIG. 3; FIG. 7 is a cross-sectional view taken along line C-C of FIG. 3; FIG. 8 is a cross-sectional view taken along line D-D of FIG. 3; and FIG. 9 is a cross-sectional view taken along line E-E of FIG. 3.

Referring now to FIGS. 3 to 9, a semiconductor device according to some embodiments may include an active pattern AP, a first gate electrode 300, a second gate electrode 800, a source/drain region 400, a source/drain contact 700 and a device isolation layer 600. In the semiconductor device according to some embodiments, the active pattern AP may include a first active pattern AP1 and a second active pattern AP2. Alternatively, the active pattern AP may include a central active pattern CAP and a branch active pattern BAP. The active pattern AP may be disposed on a peripheral circuit board/substrate 200.

The semiconductor device according to some embodiments may include a first region R1 and a second region R2. The first region R1 may include a central active pattern CAP. The central active pattern CAP may be extended in a first direction D1. The central active pattern CAP may be adjacent to the branch active pattern BAP in a second direction D2. The first direction D1 and the second direction D2 may cross each other at a vertical angle, but the embodiments are not limited thereto. For example, the first direction D1 and the second direction D2 may cross each other at a non-vertical angle.

The second region R2 may include a branch active pattern BAP and a device isolation layer 600. The branch active pattern BAP may be extended in the second direction D2 from the central active pattern CAP. The branch active patterns BAP may be spaced apart from each other in the first direction D1. The device isolation layer 600 may be disposed between the branch active patterns BAP spaced apart from each other.

The first active pattern AP1 may be extended in the second direction D2. The first active patterns AP1 may be spaced apart from each other in the first direction D1. The first active pattern AP1 may be disposed between the second active patterns AP2. The first active pattern AP1 may be extended over the first region R1 and the second region R2.

The second active pattern AP2 may be extended in the second direction D2. The second active pattern AP2 may be spaced apart from each other in the first direction D1. The second active pattern AP2 may be disposed between the first active patterns AP1. The second active pattern AP2 may be extended from the first region R1.

The first active pattern AP1 and the second active pattern AP2 may be adjacent to each other. The first active pattern AP1 and the second active pattern AP2 may be connected to each other. The central active pattern CAP may include a first active pattern AP1 and a second active pattern AP2. In detail, the central active pattern CAP may include a portion of the first active pattern AP1, which is extended from the first region R1, and an entirety of the second active pattern AP2.

The branch active pattern BAP may include a first active pattern AP1. In detail, the branch active pattern BAP may include a portion of the first active pattern AP1 extended from the second region R2. The source/drain region 400 may include an inner source/drain region 410 and an outer source/drain region 420. The inner source/drain region 410 may be disposed inside a ring portion 310 of the first gate electrode 300. In detail, in view of the layout, the inner source/drain region 410 may be surrounded by the ring portion 310 of the first gate electrode 300.

For example, the inner source/drain region 410 may include a first inner source/drain region 411 and a second inner source/drain region 412. The first inner source/drain region 411 may be disposed inside a first sub-ring portion 311. The second inner source/drain region 412 may be disposed inside a second sub-ring portion 312. The outer source/drain region 420 may be disposed outside the ring portion 310 of the first gate electrode 300. The outer source/drain region 420 may not be surrounded by the ring portion 310 of the first gate electrode 300.

For example, the outer source/drain region 420 may include first to fourth outer source/drain regions 421 to 424. The first to fourth outer source/drain regions 421 to 424 may be disposed outside the first sub-ring portion 311. The first sub-ring portion 311 may be disposed inside the first to fourth outer source/drain regions 421 to 424. The outer source/drain region 420 may be disposed on the central active pattern CAP. The outer source/drain region 420 may be disposed between extension portions 320 of the first gate electrode 300. The outer source/drain region 420 may not overlap the device isolation layer 600.

The source/drain contact 700 may include an inner source/drain contact 710 and an outer source/drain contact 720. An inner source/drain contact 710 may be disposed on the inner source/drain region 410. The inner source/drain contact 710 may be disposed inside the ring portion 310 of the first gate electrode 300. The inner source/drain contact 710 may be surrounded by the ring portion 310 of the first gate electrode 300.

The outer source/drain contact 720 may be disposed on the outer source/drain region 420. The outer source/drain contact 720 may be disposed outside the ring portion 310 of the first gate electrode 300. The outer source/drain contact 720 may be disposed between the extension portions 320 of the first gate electrode 300. The outer source/drain contact 720 may not be surrounded by the ring portion 310 of the first gate electrode 300.

The inner source/drain contact 710 and the outer source/drain contact 720 may be disposed in a zigzag shape. The inner source/drain contact 710 and the outer source/drain contact 720 may be alternately arranged. For example, the first outer source/drain contact 721 and the first inner source/drain contact 711 may be spaced apart from each other in a fourth direction D4. The first inner source/drain contact 711 and the second outer source/drain contact 722 may be disposed in a third direction D3. In this case, the first outer source/drain contact 721 and the second outer source/drain contact 722 may be spaced apart from each other in the second direction D2.

The inner source/drain contact 710 may be spaced apart from the ring portion 310 of the first gate electrode 300 as much as a first distance DS1. The outer source/drain contact 720 may be spaced apart from the ring portion 310 of the first gate electrode 300 as much as a second distance DS2. Although the first distance DS1 is shorter than the second distance DS2 in FIG. 4, the embodiments are not limited thereto. For example, the first distance DS1 may be equal to the second distance DS2. For another example, the first distance DS1 may be longer than the second distance DS2.

The first gate electrode 300 may include a ring portion 310 and an extension portion 320. The ring portion 310 and the extension portion 320 may be connected to each other. The ring portion 310 may surround the inner source/drain region 410 and the inner source/drain contact 710. In view of the layout, the ring portion 310 may have a closed ring shape. In view of the layout, the ring portion 310 may completely surround the inner source/drain contact 710. In view of the layout, the ring portion 310 may include a hole that exposes the inner source/drain contact 710. The ring portion 310 may be disposed on the central active pattern CAP. The ring portion 310 may be disposed in the first region R1.

For example, the ring portion 310 may include a first sub-ring portion 311 and a second sub-ring portion 312. The first sub-ring portion 311 may include first to fourth portions 311a to 311d. The first to fourth portions 311a to 311d may form a closed ring shape. The first to fourth portions 311a to 311d may surround the first inner source/drain contact 711. The first portion 311a may be extended in the third direction D3. The third direction D3 may cross the first direction D1 and the second direction D2. The first portion 311a may be connected to the second portion 311b and the fourth portion 311d.

The first portion 311a may be disposed between the first outer source/drain contact 721 and the first inner source/drain contact 711. The first portion 311a may be extended in the third direction D3 between the first outer source/drain contact 721 and the first inner source/drain contact 711. The first portion 311a may be disposed between the first outer source/drain region 421 and the first inner source/drain region 411. The first portion 311a, the first outer source/drain region 421 and the first inner source/drain region 411 may operate as one transistor.

The second portion 311b may be extended in the fourth direction D4. The second portion 311b may be connected to the first portion 311a and the third portion 311c. The fourth direction D4 may cross the first direction D1, the second direction D2 and the third direction D3. The third direction D3 and the fourth direction D4 may cross each other at a vertical angle, but the embodiments are not limited thereto. For example, the third direction D3 and the fourth direction D4 may cross each other at a non-vertical angle.

The second portion 311b may be disposed between the second outer source/drain contact 722 and the first inner source/drain contact 711. The second portion 311b may be extended in the fourth direction D4 between the second outer source/drain contact 722 and the first inner source/drain contact 711.

The second portion 311b may be disposed between the second outer source/drain region 422 and the first inner source/drain region 411. The second portion 311b, the second outer source/drain region 422 and the first inner source/drain region 411 may operate as one transistor in some embodiments.

The third portion 311c may be extended in the third direction D3. The third portion 311c may face the first portion 311a. The third portion 311c may be connected to the second portion 311b and the fourth portion 311d. The third portion 311c may also be disposed between the fourth outer source/drain contact 724 and the first inner source/drain contact 711. The third portion 311c may be extended in the third direction D3 between the fourth outer source/drain contact 724 and the first inner source/drain contact 711.

The third portion 311c may be disposed between the fourth outer source/drain region 424 and the first inner source/drain region 411. The third portion 311c, the fourth outer source/drain region 424 and the first inner source/drain region 411 may operate as one transistor in some embodiments.

The fourth portion 311d may be extended in the fourth direction D4. The fourth portion 311d may face the second portion 311b. The fourth portion 311d may be connected to the first portion 311a and the third portion 311c. The fourth portion 311d may be disposed between the third outer source/drain contact 723 and the first inner source/drain contact 711. The fourth portion 311d may be extended in the fourth direction D4 between the third outer source/drain contact 723 and the first inner source/drain contact 711.

The fourth portion 311d may be disposed between the third outer source/drain region 423 and the first inner source/drain region 411. The fourth portion 311d, the third outer source/drain region 423 and the first inner source/drain region 411 may operate as one transistor.

Likewise, the second sub-ring portion 312 may include fifth to eighth portions 312a to 312d. The description of the fifth to eighth portions 312a to 312d of the second sub-ring portion 312 is substantially the same as the description of the first to fourth portions 311a to 311d of the first sub-ring portion 311 and thus will be omitted.

The first sub-ring portion 311 and the second sub-ring portion 312 may be connected to each other. For example, the first sub-ring portion 311 and the second sub-ring portion 312 may extend adjacent to each other in the first direction D1. The third portion 311c and the fourth portion 311d of the first sub-ring portion 311 may be merged with the fifth portion 312a and the sixth portion 312b of the second sub-ring portion 312. The third portion 311c and the fourth portion 311d of the first sub-ring portion 311 may cross the fifth portion 312a and the sixth portion 312b of the second sub-ring portion 312.

The extension portion 320 may include a first extension portion 321 and a second extension portion 322. The first extension portion 321 may be connected to the first sub-ring portion 311. The second extension portion 322 may be connected to the second sub-ring portion 312. The first extension portion 321 and the second extension portion 322 may be spaced apart from each other in the first direction D1.

Since the description of the second extension portion 322 is substantially the same as the description of the first extension portion 321, the following description will be based on the first extension portion 321. The first extension portion 321 may include a first sub-extension portion 321a and a second sub-extension portion 321b. The first sub-extension portion 321a and the second sub-extension portion 321b may be spaced apart from each other in the second direction D2. The first sub-extension portion 321a and the second sub-extension portion 321b may be extended in the second direction D2. The first sub-extension portion 321a and the second sub-extension portion 321b may be disposed with the first inner source/drain contact 711 interposed therebetween.

The first sub-extension portion 321a may be connected to the first portion 311a and the fourth portion 311d of the first sub-ring portion 311. The first sub-extension portion 321a may be disposed between the first outer source/drain contact 721 and the third outer source/drain contact 723. The first sub-extension portion 321a may be extended in the second direction D2 between the first outer source/drain contact 721 and the third outer source/drain contact 723.

The first sub-extension portion 321a may be disposed between the first outer source/drain region 421 and the third outer source/drain region 423. For example, the first sub-extension portion 321a, the first outer source/drain region 421 and the third outer source/drain region 423 may operate as one transistor.

The first sub-extension portion 321a may be extended over the central active pattern CAP and the device isolation layer 600. The first sub-extension portion 321a may be extended over the second active pattern AP2 and the device isolation layer 600. A portion of the first sub-extension portion 321a may overlap the device isolation layer 600.

The second sub-extension portion 321b may be connected to the second portion 311b and the third portion 311c of the first sub-ring portion 311. The second sub-extension portion 321b may be disposed between the second outer source/drain contact 722 and the fourth outer source/drain contact 724. The second sub-extension portion 321b may be extended in the second direction D2 between the second outer source/drain contact 722 and the fourth outer source/drain contact 724.

The second sub-extension portion 321b may be disposed between the second outer source/drain region 422 and the fourth outer source/drain region 424. For example, the second sub-extension portion 321b, the second outer source/drain region 422 and the fourth outer source/drain region 424 may operate as one transistor. The second sub-extension portion 321b may be extended over the central active pattern CAP and the device isolation layer 600. The second sub-extension portion 321b may be extended over the second active pattern AP2 and the device isolation layer 600. A portion of the second sub-extension portion 321b may overlap the device isolation layer 600.

The first gate electrode 300 may have a first width W1 at a period where the first sub-ring portion 311 and the second sub-ring portion 312 are combined with each other. In detail, the first gate electrode 300 may have a first width W1 between the first inner source/drain contact 711 and the second inner source/drain contact 712. The ring portion 310 may have a second width W2. For example, the first to fourth portions 311a to 311d of the first sub-ring portion 311 may have a second width W2. The extension portion 320 may have a third width W3. For example, the first sub-extension portion 321a may have a third width W3.

The first width W1 may be greater than the second width W2 and the third width W3, but the embodiments are not limited thereto. For example, the first width W1, the second width W2 and the third width W3 may be the same as one another. The second width W2 and the third width W3 may be the same as each other, but the embodiments are not limited thereto. For example, the second width W2 may be smaller than the third width W3.

The second gate electrode 800 may be disposed in the second region R2. The second gate electrode 800 may cross the branch active pattern BAP and the device isolation layer 600. The second gate electrode 800 may be spaced apart from the first gate electrode 300 in the second direction D2. The second gate electrode 800 may be extended in the first direction D1. The plurality of second gate electrodes 800 may be spaced apart from each other in the second direction D2 with the first gate electrode 300 interposed therebetween. Although not shown, the second gate electrode 800 may operate as one transistor together with the source/drain region disposed on the first active pattern AP1.

The first gate electrode 300 and the second gate electrode 800 may include at least one of a metal, a metal alloy, a conductive metal nitride, a metal silicide, a doped semiconductor material, a conductive metal oxide or a conductive metal oxynitride. The first gate electrode 300 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or their combination, but is not limited thereto. The conductive metal oxide and the conductive metal oxynitride may include an oxidized form of the above-described materials, but are not limited thereto.

A gate insulating layer 301 may be extended along an upper surface of the active pattern AP. Each of the first gate electrode 300 and the second gate electrode 800 may be disposed on the gate insulating layer 301. The gate insulating layer 301 may be disposed among the first gate electrode 300 and the second gate electrode 800 and the active pattern AP.

The gate insulating layer 301 may include at least one of silicon oxide, silicon oxynitride, silicon nitride, or a high dielectric constant material having a dielectric constant higher than that of the silicon oxide. The high dielectric constant material may include one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

A gate spacer 303 may be disposed on sidewalls of the first gate electrode 300 and the second gate electrode 800. The gate spacer 303 may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC) or their combination.

A gate capping layer 302 may be disposed on the first gate electrode 300 and the second gate electrode 800. The gate capping layer 302 may be disposed between the gate spacers 303. Unlike the shown example, the gate capping layer 302 may be disposed on the first gate electrode 300, the second gate electrode 800 and the gate spacer 303. That is, the gate capping layer 302 may cover the gate spacer 303. The gate capping layer 302 may include, for example, at least one of silicon nitride (SiN), silicon oxynitride (SiON), silicon carbonitride (SiCN), silicon oxycarbonitride (SiOCN) or their combination.

The device isolation layer 600 may be disposed in the second region R2. The device isolation layer 600 may be disposed between the branch active patterns BAP. The device isolation layer 600 may be extended in the second direction D2. The device isolation layer 600 may overlap a portion of the extension portion 320 of the first gate electrode 300.

The device isolation layer 600 may not overlap the outer source/drain contact 720. In detail, the device isolation layer 600 may not overlap the outer source/drain contact 720 in the first direction D1. In the first direction D1, the device isolation layer 600 may not be disposed between the outer source/drain contacts 720.

The first gate electrode 300 having a ring portion 310 may operate as a gate of a plurality of transistors between a plurality of inner source/drain regions 410 and a plurality of outer source/drain regions 420. The first gate electrode 300 having a ring portion 310 may reduce an area occupied by a gate electrode of a plurality of transistors that include a plurality of inner source/drain regions 410 and a plurality of outer source/drain regions 420. Also, the inner source/drain contact 710 and the outer source/drain contact 720, which are disposed in a zigzag shape, may reduce an area occupied by a plurality of transistors.

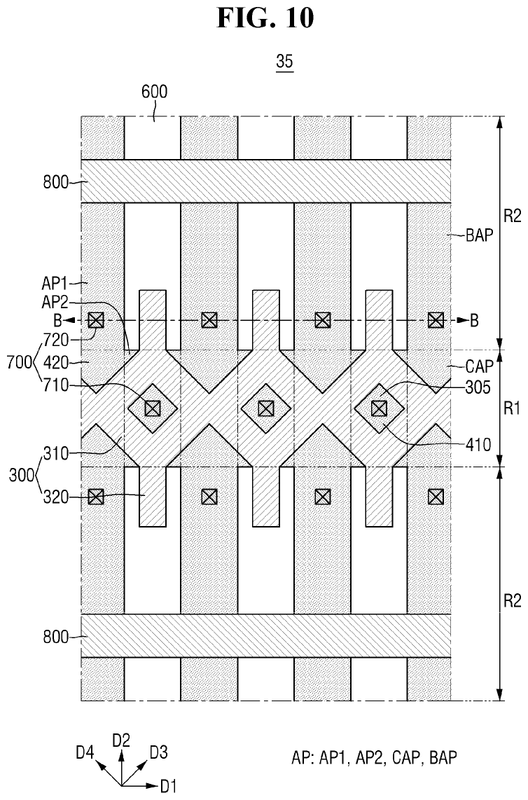

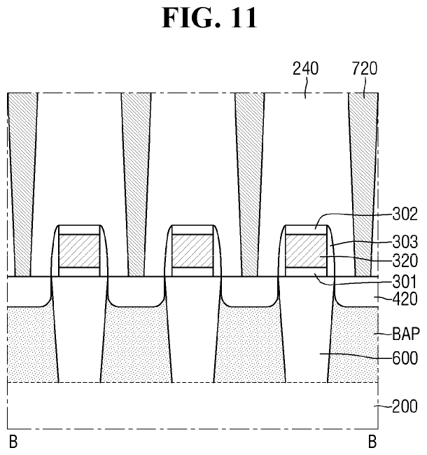

FIG. 10 is a layout view illustrating a semiconductor device according to some other embodiments. FIG. 11 is a cross-sectional view taken along line B-B of FIG. 10. For convenience of description, the following description will be based on differences from those described with reference to FIGS. 3 to 9. Referring to FIGS. 10 and 11, the outer source/drain region 420 and the outer source/drain contact 720 may be disposed on the branch active pattern BAP. The outer source/drain region 420 and the outer source/drain contact 720 may be disposed between the extension portions 320 of the first gate electrode 300. The outer source/drain region 420 and the outer source/drain contact 720 may overlap the device isolation layer 600.

The device isolation layer 600 may overlap the outer source/drain contact 720. In detail, the device isolation layer 600 may overlap the outer source/drain contact 720 in the first direction D1. In the first direction D1, the device isolation layer 600 may be disposed between the outer source/drain contacts 720.

The device isolation layer 600 disposed between the outer source/drain region 420 and the outer source/drain contact 720 may insulate two outer source/drain regions 420 adjacent to each other in the first direction D1. Therefore, the device isolation layer 600 may prevent the two outer source/drain regions 420 and the first gate electrode 300 from operating as transistors.

Referring to FIG. 11, on the cross-sectional view taken along the first direction D1, the device isolation layer 600 may be disposed between the outer source/drain regions 420 below the extension portion 320 of the first gate electrode 300.

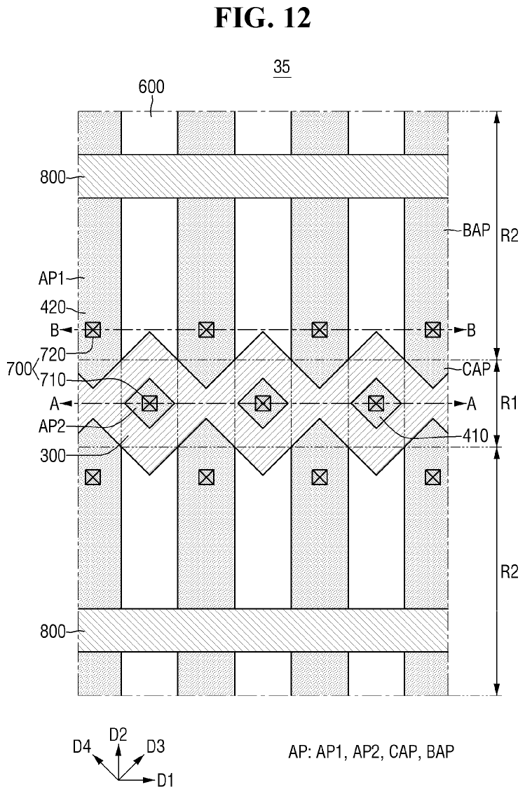

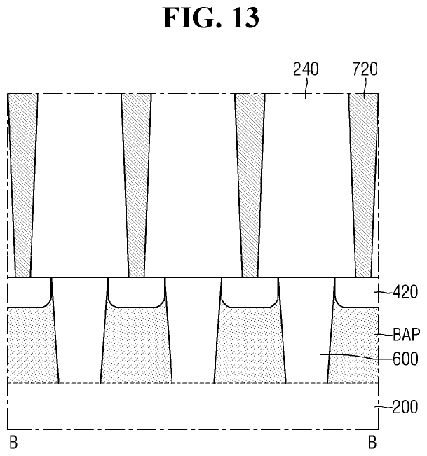

FIG. 12 is a layout view illustrating a semiconductor device according to some other embodiments. FIG. 13 is a cross-sectional view taken along line B-B of FIG. 12. For convenience of description, the following description will be based on differences from those described with reference to FIGS. 3 to 9. Referring to FIGS. 12 and 13, the first gate electrode 300 may include only a ring portion 310. The first gate electrode 300 may not include an extension portion 320. That is, the extension portion 320 extended from the ring portion 310 toward the second region R2 may not be disposed. In detail, referring to FIG. 13, the first gate electrode 300 may not be disposed on the device isolation layer 600 on the cross-sectional view taken along the outer source/drain contact 720 in the first direction D1.

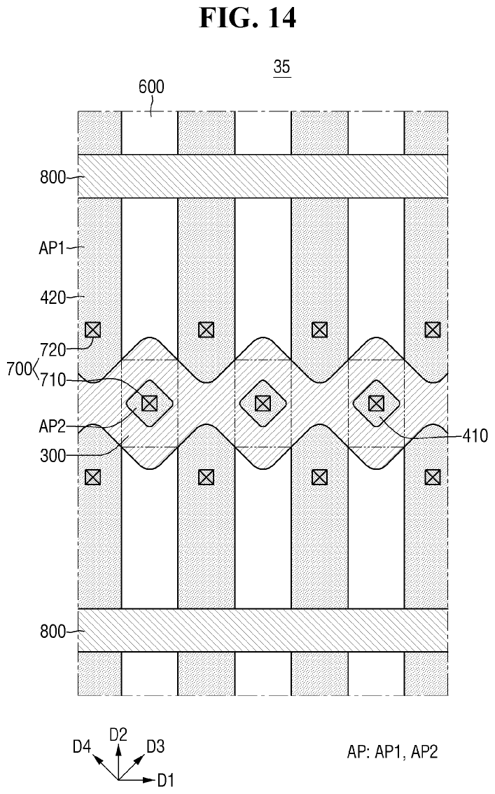

FIG. 14 is a layout view illustrating a semiconductor device according to some other embodiments. For convenience of description, the following description will be based on differences from those described with reference to FIGS. 12 and 13. Referring to FIG. 14, the first gate electrode 300 may have a rounded shape on the layout view. The ring portion 310 of the first gate electrode 300 may have curved sides.

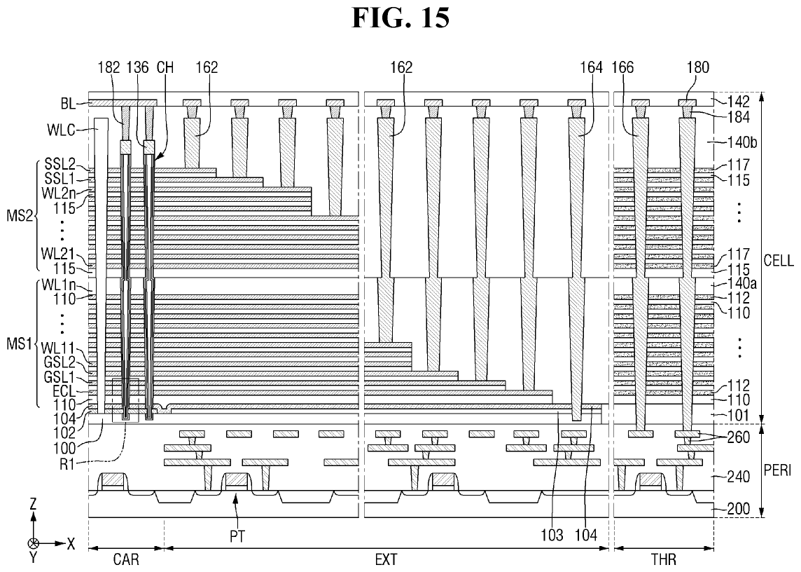

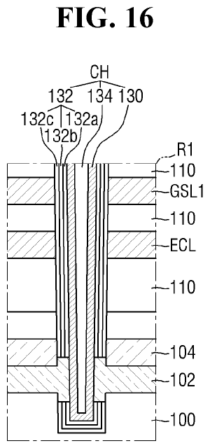

FIG. 15 is a cross-sectional view illustrating a semiconductor device according to some embodiments. FIG. 16 is an enlarged view illustrating a region R1 of FIG. 15. Referring to FIGS. 15 and 16, the semiconductor device according to some embodiments includes a memory cell region CELL and a peripheral circuit region PERI.

The memory cell region CELL may include a cell substrate 100, an insulating substrate 101, mold structures MS1 and MS2, interlayer insulating layers 140a and 140b, a channel structure CH, a word line cutting line WLC, a first partial isolation region WC1, a second partial isolation region WC2, a bit line BL, a cell contact 162, a source contact 164, a through via 166 and a first wiring structure 180.

The cell substrate 100 may include, for example, a semiconductor substrate such as a silicon substrate, a germanium substrate or a silicon-germanium substrate. Alternatively, the cell substrate 100 may include a silicon-on-insulator (SOI) substrate or a germanium-on-insulator (GOI) substrate. In some embodiments, the cell substrate 100 may include impurities. For example, the cell substrate 100 may include n-type impurities (e.g., phosphorus (P), arsenic (As), etc.). The cell substrate 100 may include a cell array region CAR and an extension region EXT.

A memory cell array (e.g., 20 of FIG. 1) including a plurality of memory cells may be formed in the cell array region CAR. For example, the channel structure CH, the bit line BL and the gate electrodes ECL, GSL1, GSL2, WL11 to WL1n, WL21 to WL2n, SSL1 and SSL2, which will be described later, may be disposed in the cell array region CAR. In the following description, a surface of the cell substrate 100, on which the memory cell array is disposed, may be referred to as a front side of the cell substrate 100. On the contrary, a surface of the cell substrate 100, which is opposite to the front side of the cell substrate 100, may be referred to as a back side of the cell substrate 100. The extension region EXT may be disposed near the cell array region CAR. The gate electrodes ECL, GSL1, GSL2, WL11 to WL1n, WL21 to WL2n, SSL1 and SSL2, which will be described later, may be stacked in a stepped shape.

In some embodiments, the cell substrate 100 may further include a through region THR. The through region THR may be disposed inside the cell array region CAR and the extension region EXT, or may be disposed outside the cell array region CAR and the extension region EXT. The through via 166, which will be described later, may be disposed in the through region THR.

The insulating substrate 101 may be formed in the cell substrate 100 of the extension region EXT. The insulating substrate 101 may form an insulating region in the cell substrate 100 of the extension region EXT. The insulating substrate 101 may include, for example, at least one of silicon oxide, silicon nitride, silicon oxynitride or silicon carbide, but is not limited thereto. In some embodiments, the insulating substrate 101 may be formed in the cell substrate 100 of the through region THR.

A lower surface of the insulating substrate 101 is illustrated as being disposed on a lower surface and a coplanar surface of the cell substrate 100, but this is only exemplary. As another example, the lower surface of the insulating substrate 101 may be lower than that of the cell substrate 100.

The mold structures MS1 and MS2 may be formed on the front side of the cell substrate 100. The mold structures MS1 and MS2 may include a plurality of gate electrodes ECL, GSL1, GSL2, WL11 to WL1n, WL21 to WL2n, SSL1 and SSL2 and a plurality of mold insulating layers 110 and 115, which are stacked on the cell substrate 100. Each of the gate electrodes ECL, GSL1, GSL2, WL11 to WL1n, WL21 to WL2n, SSL1 and SSL2 and each of the mold insulating layers 110 and 115 may have a layered structure extended in parallel with the front side of the cell substrate 100. The gate electrodes ECL, GSL1, GSL2, WL11 to WL1n, WL21 to WL2n, SSL1 and SSL2 may be sequentially stacked on the cell substrate 100 by being spaced apart from one another by the mold insulating layers 110 and 115.

In some embodiments, the mold structures MS1 and MS2 may include a first mold structure MS1 and a second mold structure MS2, which are sequentially stacked on the cell substrate 100. The first mold structure MS1 may include gate electrodes ECL, GSL1, GSL2 and WL11 to WL1n and first mold insulating layers 110, which are alternately stacked on the cell substrate 100. In some embodiments, the gate electrodes ECL, GSL1, GSL2 and WL11 to WL1n may include an erase control line ECL, ground selection lines GSL1 and GSL2 and a plurality of first word lines WL11 to WL1n, which are sequentially stacked on the cell substrate 100. The ground selection lines GSL1 and GSL2 may include a first ground selection line GSL1 and a second ground selection line GSL2, which are sequentially stacked. Although the gate electrodes ECL, GSL1, GSL2 and WL11 to WL1n are illustrated as including only two ground selection lines GSL1 and GSL2, this is only exemplary, and the gate electrodes ECL, GSL1, GSL2 and WL11 to WL1n may include three or more ground selection lines. In some other embodiments, the erase control line ECL may be omitted.

The second mold structure MS2 may include gate electrodes WL21 to WL2n, SSL1 and SSL2 and second mold insulating layers 115, which are alternately stacked on the first mold structure MS1. In some embodiments, the gate electrodes WL21 to WL2n, SSL1 and SSL2 may include a plurality of second word lines WL21 to WL2n and string selection lines SSL1 and SSL2, which are sequentially stacked on the first mold structure MS1. The string selection lines SSL1 and SSL2 may include a first string selection line SSL1 and a second string selection line SSL2, which are sequentially stacked. Although the gate electrodes WL21 to WL2n, SSL1 and SSL2 are illustrated as including only two string selection lines SSL1 and SSL2, this is only exemplary, and the gate electrodes WL21 to WL2n, SSL1 and SSL2 may include three or more string selection lines.

Each of the gate electrodes ECL, GSL1, GSL2, WL11 to WL1n, WL21 to WL2n, SSL1 and SSL2 may include a conductive material, for example, metal such as tungsten (W), cobalt (Co) and nickel (Ni), or a semiconductor material such as silicon, but is not limited thereto. Each of the mold insulating layers 110, 115 may include an insulating material, for example, at least one of silicon oxide, silicon nitride or silicon oxynitride, but is not limited thereto.

In some embodiments, the mold structure MS1 and MS2 of the through region THR may include a plurality of mold sacrificial layers 112 and 117 and a plurality of mold insulating layers 110 and 115, which are alternately stacked on the cell substrate 100 and/or the insulating substrate 101. Each of the mold sacrificial layers 112 and 117 and each of the mold insulating layers 110 and 115 may have a layered structure in which the layers are extended in parallel with an upper surface of the cell substrate 100. The mold sacrificial layers 112 and 117 may be sequentially stacked on the cell substrate 100 by being spaced apart from each other by the mold insulating layers 110 and 115.

In some embodiments, the first mold structure MS1 of the through region THR may include first mold sacrificial layers 112 and first mold insulating layers 110, which are alternately stacked on the cell substrate 100, and the second mold structure MS2 of the through region THR may include second mold sacrificial layers 117 and second mold insulating layers 115, which are alternately stacked on the first mold structure MS1.

Each of the mold sacrificial layers 112 and 117 may include an insulating material, for example, at least one of silicon oxide, silicon nitride or silicon oxynitride, but is not limited thereto. In some embodiments, the mold sacrificial layers 112 and 117 may include a material having an etch selectivity with respect to the mold insulating layers 110 and 115. For example, the mold insulating layers 110 and 115 may include silicon oxide, and the mold sacrificial layers 112 and 117 may include silicon nitride.

The interlayer insulating layers 140a and 140b may be formed on the cell substrate 100 to cover the mold structures MS1 and MS2. In some embodiments, the interlayer insulating layers 140a and 140b may include a first interlayer insulating layer 140a and a second interlayer insulating layer 140b, which are sequentially stacked on the cell substrate 100. The first interlayer insulating layer 140a may cover the first mold structure MS1, and the second interlayer insulating layer 140b may cover the second mold structure MS2. The interlayer insulating layers 140a and 140b may include, for example, at least one of silicon oxide, silicon oxynitride or a low dielectric constant (low-k) material having a dielectric constant lower than that of silicon oxide, but is not limited thereto.

The channel structure CH may be formed in the mold structures MS1 and MS2 of the cell array region CAR. The channel structure CH may be extended in a vertical direction (hereinafter, referred to as a fifth direction Z) crossing the upper surface of the cell substrate 100, thereby passing through the mold structures MS1 and MS2. For example, the channel structure CH may have a pillar shape (for example, cylindrical shape) extended in the fifth direction Z. Therefore, the channel structure CH may cross each of the gate electrodes ECL, GSL1, GSL2, WL11 to WL1n, WL21 to WL2n, SSL1 and SSL2. In some embodiments, the channel structure CH may have a bent portion between the first mold structure MS1 and the second mold structure MS2.

As shown in FIGS. 15 and 16, the channel structure CH may include a semiconductor pattern 130 and an information storage layer 132. The semiconductor pattern 130 may be extended in the fifth direction Z to pass through the mold structures MS1 and MS2. The semiconductor pattern 130 is shown as having a cup shape, but this is only exemplary. For example, the semiconductor pattern 130 may have various shapes such as a cylindrical shape, a rectangular barrel shape and a filled pillar shape. The semiconductor pattern 130 may include, for example, a semiconductor material such as monocrystalline silicon, polycrystalline silicon, an organic semiconductor material and a carbon nanostructure, but is not limited thereto.

The information storage layer 132 may be interposed between the semiconductor pattern 130 and each of the gate electrodes ECL, GSL1, GSL2, WL11 to WL1n, WL21 to WL2n, SSL1 and SSL2. For example, the information storage layer 132 may be extended along an outer side of the semiconductor pattern 130. The information storage layer 132 may include, for example, at least one of silicon oxide, silicon nitride, silicon oxynitride or a high dielectric constant material having a dielectric constant higher than that of silicon oxide. The high dielectric constant material may include, for example, at least one of aluminum oxide, hafnium oxide, lanthanum oxide, tantalum oxide, titanium oxide, lanthanum hafnium oxide, lanthanum aluminum oxide, dysprosium scandium oxide or their combination.

In some embodiments, the information storage layer 132 may be formed of a multi-layer. For example, as shown in FIG. 16, the information storage layer 132 may include a tunnel insulating layer 132a, a charge storage layer 132b and a blocking insulating layer 132c, which are sequentially stacked on the outer side of the semiconductor pattern 130. The tunnel insulating layer 132a may include, for example, silicon oxide or a high dielectric constant material (e.g., aluminum oxide (Al₂O₃), hafnium oxide (HfO₂)) having a dielectric constant higher than that of silicon oxide. The charge storage layer 132b may include, for example, silicon nitride. The blocking insulating layer 132c may include, for example, silicon oxide or a high dielectric constant material (e.g., aluminum oxide (Al₂O₃), hafnium oxide (HfO₂)) having a dielectric constant higher than that of silicon oxide.

In some embodiments, the channel structure CH may further include a filling pattern 134. The filling pattern 134 may be formed to fill the inside of the semiconductor pattern 130 having a cup shape. The filling pattern 134 may include an insulating material, for example, silicon oxide, but is not limited thereto.

In some embodiments, the channel structure CH may further include a channel pad 136. The channel pad 136 may be formed to be connected to an upper portion of the semiconductor pattern 130. For example, the channel pad 136 may include, for example, polysilicon doped with impurities, but is not limited thereto.

In some embodiments, the plurality of channel structures CH may be arranged in a zigzag shape. The plurality of channel structures CH may be alternately arranged in the first direction X and the second direction Y in parallel with the upper surface of the cell substrate 100. The plurality of channel structures CH arranged in a zigzag shape may more improve the degree of integration of the semiconductor device. In some embodiments, the plurality of channel structures CH may be arranged in a honeycomb shape.

In some embodiments, first source structures 102 and 104 may be formed on the cell substrate 100. The first source structures 102 and 104 may be interposed between the cell substrate 100 and the mold structures MS1 and MS2. For example, the first source structures 102 and 104 may be extended along the upper surface of the cell substrate 100. The first source structures 102 and 104 may be formed to be connected to the semiconductor pattern 130 of the channel structure CH. For example, as shown in FIG. 16, the first source structures 102 and 104 may be in contact with the semiconductor pattern 130 by passing through the information storage layer 132. The first source structures 102 and 104 may be provided as a common source line (e.g., CSL in FIG. 2) of the semiconductor device. The first source structures 102 and 104 may include, for example, polysilicon doped with impurities or a metal, but is not limited thereto.

In some embodiments, the channel structure CH may pass through the first source structures 102 and 104. For example, a lower portion of the channel structure CH may be disposed in the cell substrate 100 by passing through the first source structures 102 and 104. In some embodiments, the first source structures 102 and 104 may be formed of multiple layers. For example, the first source structures 102 and 104 may include a first source layer 102 and a second source layer 104, which are sequentially stacked on the cell substrate 100. Each of the first source layer 102 and the second source layer 104 may include, but is not limited to, polysilicon doped with impurities or polysilicon with which impurities are not doped. The first source layer 102 may be provided as a common source line (e.g., CSL in FIG. 2) of the semiconductor device in contact with the semiconductor pattern 130. The second source layer 104 may be used as a support layer for preventing collapse or falling of the mold stack in a replacement process for forming the first source layer 102.

Although not shown, a base insulating layer may be interposed between the cell substrate 100 and the first source structures 102 and 104. The base insulating layer may include, for example, at least one of silicon oxide, silicon nitride or silicon oxynitride, but is not limited thereto. In some embodiments, the first source structures 102 and 104 may not be formed in the extension region EXT in which the insulating substrate 101 is formed. Although shown that an upper surface of the insulating substrate 101 is disposed on upper surfaces and coplanar surfaces of the first source structures 102 and 104, this is only exemplary. As another example, the upper surface of the insulating substrate 101 may be higher than the upper surfaces of the first source structures 102 and 104.

In some embodiments, a source sacrificial layer 103 may be formed on a portion of the cell substrate 100. For example, the source sacrificial layer 103 may be formed on a portion of the cell substrate 100 in the extension region EXT. The source sacrificial layer 103 may include a material having an etch selectivity with respect to the mold insulating layers 110 and 115. For example, the mold insulating layers 110 and 115 may include silicon oxide, and the source sacrificial layer 103 may include silicon nitride. The source sacrificial layer 103 may be a layer remaining after a portion of the first source structures 102 and 104 is replaced with the first source layer 102 during the manufacturing process of the first source structures 102 and 104.

The word line cutting line WLC may be extended in the first direction X to cut the mold structure MS1 and MS2. The word line cutting line WLC may completely cut the mold structures MS1 and MS2. For example, the word line cutting line WLC may be continuously extended in the first direction X. The mold structures MS1 and MS2 may be divided by the word line cutting line WLC arranged along the second direction Y to form a plurality of memory cell blocks (e.g., BLK1 to BLKn in FIG. 1).

Although not shown, a string isolation structure may be extended in the first direction X to cut the string selection lines SSL1 and SSL2. For example, the string isolation structure formed in the first cell block BLK1 may divide the string selection lines SSL1 and SSL2 into a first region and a second region, respectively. Therefore, the first string selection line SSL1 of the first region and the first string selection line SSL1 of the second region may be separately controlled, and the second string selection line SSL2 of the first region and the second string selection line SSL2 of the second region may be separately controlled. The string isolation structure may include an insulating material, for example, at least one of silicon oxide, silicon nitride or silicon oxynitride, but is not limited thereto.

The bit line BL may be formed on the mold structures MS1 and MS2. The bit line BL may be extended in the second direction Y to cross the word line cutting line WLC. Also, the bit line BL may be extended in the second direction Y and connected to the plurality of channel structures CH arranged along the second direction Y. For example, a bit line contact 182 connected to an upper portion of each of the channel structures CH may be formed in the second interlayer insulating layer 140b. The bit line BL may be electrically connected to the channel structures CH through the bit line contact 182.

The cell contact 162 may be connected to the respective gate electrodes ECL, GSL1, GSL2, WL11 to WL1n, WL21 to WL2n, SSL1 and SSL2. For example, the cell contacts 162 may be extended in the fifth direction Z in the interlayer insulating layers 140a and 140b and connected to the respective gate electrodes ECL, GSL1, GSL2, WL11 to WL1n, WL21 to WL2n, SSL1 and SSL2. In some embodiments, the cell contact 162 may have a bent portion between the first mold structure MS1 and the second mold structure MS2.

The source contact 164 may be connected to the first source structures 102 and 104. For example, the source contact 164 may be extended in the fifth direction Z in the interlayer insulating layers 140a and 140b and connected to the cell substrate 100. In some embodiments, the source contact 164 may have a bent portion between the first mold structure MS1 and the second mold structure MS2.

The through via 166 may be disposed in the through region THR. For example, the through via 166 may be extended in the fifth direction Z in the mold structures MS1 and MS2 of the through region THR. In some embodiments, the through via 166 may have a bent portion between the first mold structure MS1 and the second mold structure MS2. The through via 166 is illustrated as passing through the mold structures MS1 and MS2, but this is only exemplary. As another example, the through via 166 may be disposed outside the mold structures MS1 and MS2 so as not to pass through the mold structures MS1 and MS2.

Each of the cell contact 162, the source contact 164 and the through via 166 may be connected to the first wiring structure 180 on the interlayer insulating layers 140a and 140b. For example, a first inter-wiring insulating layer 142 may be formed on the second interlayer insulating layer 140b. The first wiring structure 180 may be formed in the first inter-wiring insulating layer 142. Each of the cell contact 162, the source contact 164 and the through via 166 may be connected to the first wiring structure 180 by a contact via 184. Although not shown in detail, the first wiring structure 180 may be connected to the bit line BL.

The peripheral circuit region PERI may include a peripheral circuit board 200, a peripheral circuit element PT and a second wiring structure 260. The peripheral circuit board 200 may be disposed below the cell substrate 100. For example, an upper surface of the peripheral circuit board 200 may face the lower surface of the cell substrate 100. The peripheral circuit board 200 may include, for example, a semiconductor substrate such as a silicon substrate, a germanium substrate or a silicon-germanium substrate. Alternatively, the peripheral circuit board 200 may include a silicon-on-insulator (SOI) substrate or a germanium-on-insulator (GOI) substrate.

The peripheral circuit element PT may be formed on the peripheral circuit board 200. The peripheral circuit element PT may constitute a peripheral circuit (e.g., 30 in FIG. 1) that controls the operation of the semiconductor device. For example, the peripheral circuit element PT may include control logic (e.g., 37 in FIG. 1), a row decoder (e.g., 33 in FIG. 1) and a page buffer (e.g., 35 in FIG. 1). In the following description, a surface of the peripheral circuit board 200, on which the peripheral circuit element PT is disposed, may be referred to as a front side of the peripheral circuit board 200. On the contrary, the surface of the peripheral circuit board 200, which is opposite to the front side of the peripheral circuit board 200, may be referred to as a back side of the peripheral circuit board 200.

The peripheral circuit element PT may include, for example, a transistor, but is not limited thereto. For example, the peripheral circuit element PT may include various passive elements such as a capacitor, a resistor and an inductor as well as various active elements such as a transistor. The structure of the semiconductor device, which is described with reference to FIGS. 3 to 14, may be disposed in the peripheral circuit region PERI. For example, the peripheral circuit element PT of the peripheral circuit region PERI may include the first gate electrode 300 that includes the ring portion 310, which is described with reference to FIGS. 3 to 14. For example, a transistor of a page buffer circuit in the peripheral circuit region PERI may include an outer source/drain region 420, an inner source/drain region 410 and a ring portion 310 of the first gate electrode 300.

In some embodiments, the back side of the cell substrate 100 may face the front side of the peripheral circuit board 200. For example, a second inter-wiring insulating layer 240 covering the peripheral circuit element PT may be formed on the front side of the peripheral circuit board 200. The cell substrate 100 and/or the insulating substrate 101 may be stacked on an upper surface of the second inter-wiring insulating layer 240.

The first wiring structure 180 may be connected to the peripheral circuit element PT through the through via 166. For example, the second wiring structure 260 connected to the peripheral circuit element PT may be formed in the second inter-wiring insulating layer 240. The through via 166 may be extended in the fifth direction Z to connect the first wiring structure 180 with the second wiring structure 260. Therefore, the bit line BL, each of the gate electrodes ECL, GSL1, GSL2, WL11 to WL1n, WL21 to WL2n, SSL1 and SSL2, and/or the first source structures 102 and 104 may be electrically connected to the peripheral circuit element PT.

In some embodiments, the through via 166 may connect the first wiring structure 180 with the second wiring structure 260 by passing through the insulating substrate 101. As a result, the through via 166 may be electrically separated from the cell substrate 100.

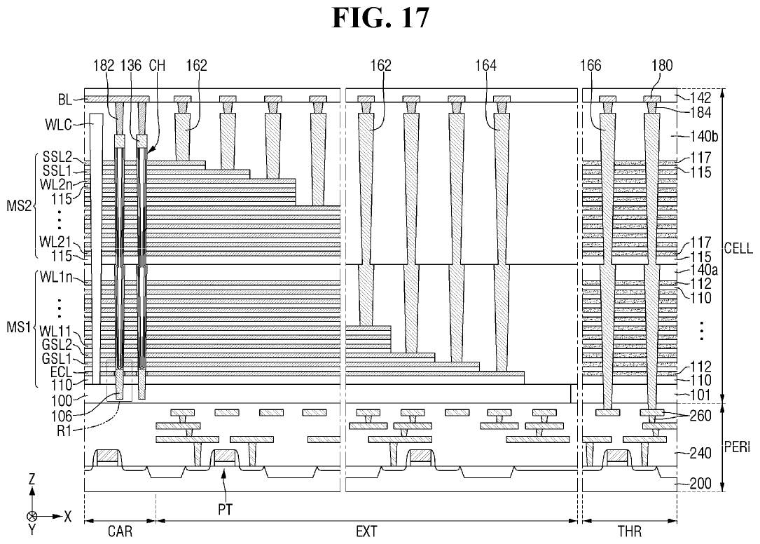

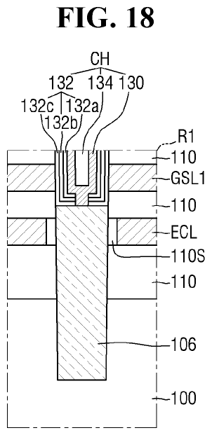

FIG. 17 is a cross-sectional view illustrating a semiconductor device according to some other embodiments. FIG. 18 is an enlarged view illustrating a region R1 of FIG. 17. For convenience of description, the following description will be based on differences from those described with reference to FIGS. 15 and 16. Referring to FIGS. 17 and 18, the semiconductor device according to some embodiments includes a second source structure 106.

The second source structure 106 may be formed on the cell substrate 100. Although a lower portion of the second source structure 106 is illustrated as being disposed in the cell substrate 100, this is only exemplary. The second source structure 106 may be connected to the semiconductor pattern 130 of the channel structure CH. For example, the semiconductor pattern 130 may be in contact with an upper surface of the second source structure 106 by passing through the information storage layer 132. The second source structure 106 may be formed by, for example, a selective epitaxial growth process from the cell substrate 100, but is not limited thereto.

In some embodiments, the upper surface of the second source structure 106 may cross a portion of the gate electrodes ECL, GSL1, GSL2, WL11 to WL1n, WL21 to WL2n, SSL1 and SSL2. For example, the upper surface of the second source structure 106 may be formed to be higher than an upper surface of the erase control line ECL. In this case, a gate insulating layer 110S may be interposed between the second source structure 106 and the gate electrode (e.g., erase control line ECL) crossing the second source structure 106.

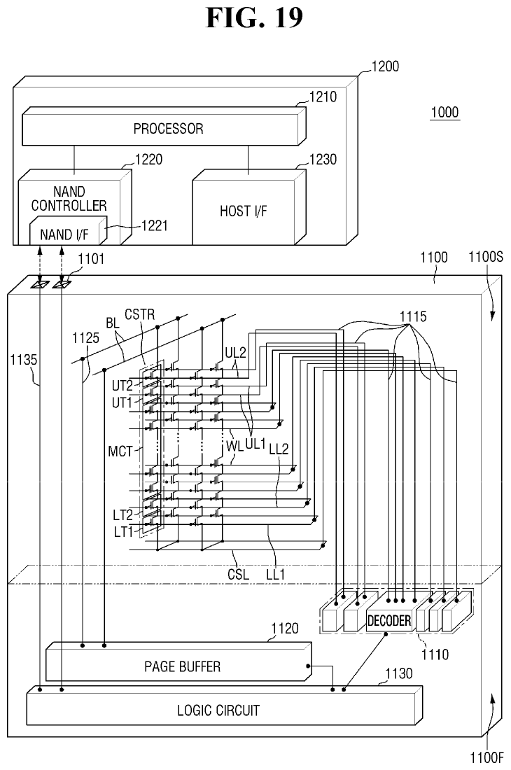

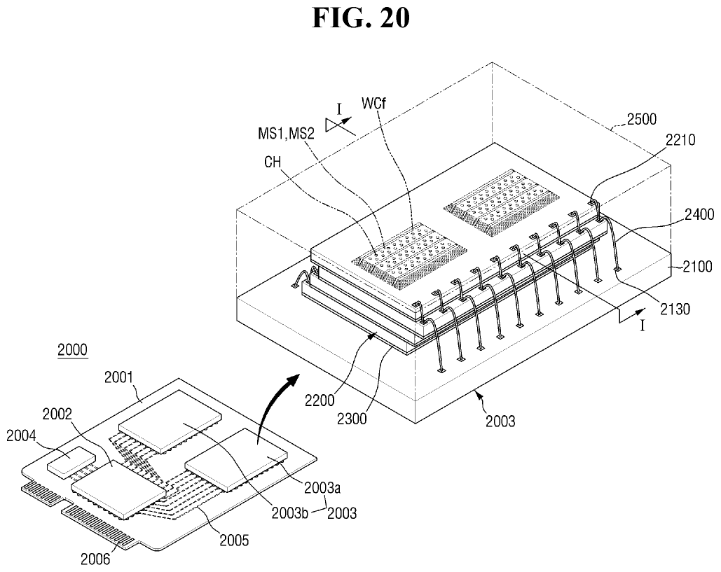

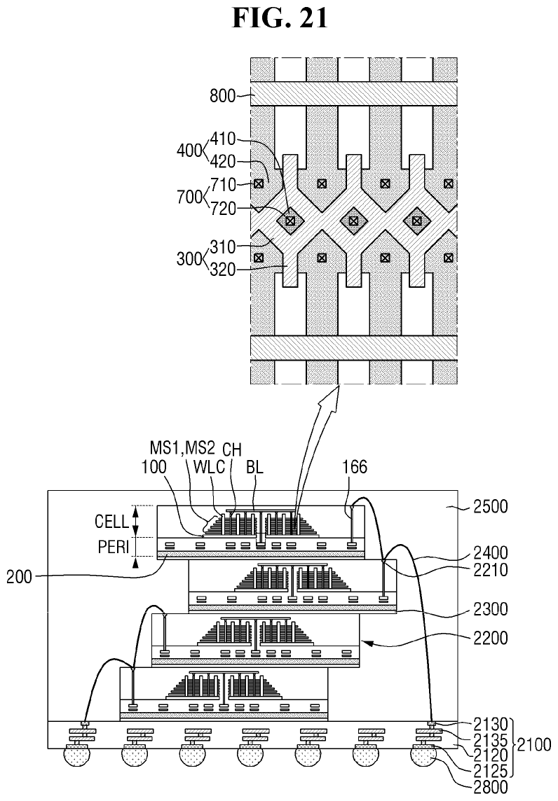

FIG. 19 is an exemplary block diagram illustrating an electronic system according to some embodiments. FIG. 20 is an exemplary perspective view illustrating an electronic system according to some embodiments. FIG. 21 is a schematic cross-sectional view taken along line I-I of FIG. 20. Referring to FIG. 19, an electronic system 1000 according to some embodiments may include a semiconductor device 1100 and a controller 1200 electrically connected to the semiconductor device 1100. The electronic system 1000 may be a storage device including one or a plurality of semiconductor devices 1100, or an electronic device including the storage device. For example, the electronic system 1000 may be a solid state drive (SSD) device, a universal serial bus (USB), a computing system, a medical device or a communication device, which includes one or more non-volatile memory devices 1100.

The semiconductor device 1100 may be a non-volatile memory device (e.g., NAND flash memory device), and may be, for example, the semiconductor device described with reference to FIGS. 1 to 18. The semiconductor device 1100 may include a first structure 1100F and a second structure 1100S on the first structure 1100F.

The first structure 1100F may be a peripheral circuit structure that includes a decoder circuit 1110 (e.g., the row decoder 33 in FIG. 1), a page buffer 1120 (e.g., the page buffer 35 in FIG. 1), and a logic circuit 1130 (e.g., the control logic 37 in FIG. 1).

The second structure 1100S may include a common source line CSL, a plurality of bit lines BL and a plurality of cell strings CSTR, which are described with reference to FIG. 2. The cell strings CSTR may be connected to the decoder circuit 1110 through a word line WL, at least one string selection line SSL and at least one ground selection line GSL. In addition, the cell strings CSTR may be connected to the page buffer 1120 through the bit lines BL.

In some embodiments, the common source line CSL and the cell strings CSTR may be electrically connected to the decoder circuit 1110 through first connection lines 1115 extended from the first structure 1100F to the second structure 1100S. The first connection lines 1115 may correspond to the through via 166 described with reference to FIGS. 15 to 18. That is, the through via 166 may electrically connect each of the gate electrodes ECL, GSL, WL and SSL with the decoder circuit 1110 (e.g., the row decoder 33 in FIG. 1).

In some embodiments, the bit lines BL may be electrically connected to the page buffer 1120 through second connection lines 1125 extended from the first structure 1100F to the second structure 1100S. The second connection lines 1125 may correspond to the through via 166 described with reference to FIGS. 15 to 18. That is, the through via 166 may electrically connect the bit lines BL with the page buffer 1120 (e.g., the page buffer 35 in FIG. 1).

The semiconductor device 1100 may perform communication with the controller 1200 through an input/output pad 1101 electrically connected to the logic circuit 1130 (e.g., the control logic 37 in FIG. 1). The input/output pad 1101 may be electrically connected to the logic circuit 1130 through an input/output connection line 1135 extended from the first structure 1100F to the second structure 1100S.

The controller 1200 may include a processor 1210, a NAND controller 1220 and a host interface 1230. In some embodiments, the electronic system 1000 may include a plurality of semiconductor devices 1100, and in this case, the controller 1200 may control the plurality of semiconductor devices 1100. The processor 1210 may control overall operations of the electronic system 1000 including the controller 1200. The processor 1210 may operate in accordance with predetermined firmware, and may control the NAND controller 1220 to access the semiconductor device 1100. The NAND controller 1220 may include a NAND interface 1221 for processing communication with the semiconductor device 1100. A control command for controlling the semiconductor device 1100, data to be written in the memory cell transistors MCT of the semiconductor device 1100, data to be read from the memory cell transistors MCT of the semiconductor device 1100 and the like may be transmitted through the NAND interface 1221. The host interface 1230 may provide a communication function between the electronic system 1000 and an external host. When a control command is received from the external host through the host interface 1230, the processor 1210 may control the semiconductor device 1100 in response to the control command.

Referring to FIGS. 20 and 21, the electronic system according to some embodiments may include a main board 2001, a main controller 2002 packaged in the main board 2001, one or more semiconductor packages 2003, and a DRAM 2004. The semiconductor package 2003 and the DRAM 2004 may be connected to the main controller 2002 by wiring patterns 2005 formed in the main board 2001.

The main board 2001 may include a connector 2006 that includes a plurality of pins coupled with the external host. The number and arrangement of the plurality of pins in the connector 2006 may be varied depending on a communication interface between the electronic system 2000 and the external host. In some embodiments, the electronic system 2000 may perform communication with the external host in accordance with any one of interfaces such as a Universal Serial Bus (USB), a Peripheral Component Interconnect Express (PCI-Express), Serial Advanced Technology Attachment (SATA), and M-Phy for Universal Flash Storage (UFS). In some embodiments, the electronic system 2000 may operate in accordance with a power source supplied from the external host through the connector 2006. The electronic system 2000 may further include a power management integrated circuit (PMIC) that distributes the power source supplied from the external host to the main controller 2002 and the semiconductor package 2003. The main controller 2002 may write data in the semiconductor package 2003 or read the data from the semiconductor package 2003, and may improve the operating speed of the electronic system 2000.

The DRAM 2004 may be a buffer memory for mitigating a speed difference between the semiconductor package 2003 that is a data storage space and the external host. The DRAM 2004 included in the electronic system 2000 may also operate as a kind of a cache memory, and may provide a space for temporarily storing data in a control operation for the semiconductor package 2003. When the DRAM 2004 is included in the electronic system 2000, the main controller 2002 may further include a DRAM controller for controlling the DRAM 2004, in addition to the NAND controller for controlling the semiconductor package 2003.

The semiconductor package 2003 may include a first semiconductor package 2003a and a second semiconductor package 2003b, which are spaced apart from each other. Each of the first semiconductor package 2003a and the second semiconductor package 2003b may be a semiconductor package that includes a plurality of semiconductor chips 2200. Each of the first semiconductor package 2003a and the second semiconductor package 2003b may include a package substrate 2100, semiconductor chips 2200 on the package substrate 2100, adhesive layers 2300 disposed on a lower surface of each of the semiconductor chips 2200, a connection structure 2400 for electrically connecting the semiconductor chips 2200 with the package substrate 2100, and a molding layer 2500 covering the semiconductor chips 2200 and the connection structure 2400 on the package substrate 2100.

The package substrate 2100 may be a printed circuit board that includes package upper pads 2130. Each semiconductor chip 2200 may include an input/output pad 2210. The input/output pad 2210 may correspond to the input/output pad 1101 of FIG. 19.

In some embodiments, the connection structure 2400 may be a bonding wire for electrically connecting the input/output pad 2210 with the package upper pads 2130. Therefore, in each of the first semiconductor package 2003a and the second semiconductor package 2003b, the semiconductor chips 2200 may be electrically connected to each other in a bonding wire manner, and may be electrically connected to the package upper pads 2130 of the package substrate 2100. In some embodiments, in each of the first semiconductor package 2003a and the second semiconductor package 2003b, the semiconductor chips 2200 may be electrically connected to each other by a connection structure that includes a through silicon via (TSV), instead of the connection structure 2400 of the bonding wire manner.

In some embodiments, the main controller 2002 and the semiconductor chips 2200 may be included in one package. In some embodiments, the main controller 2002 and the semiconductor chips 2200 may be packaged in a separate interposer substrate different from the main board 2001, and the main controller 2002 may be connected with the semiconductor chips 2200 by a wiring formed in the interposer substrate.

In some embodiments, the package substrate 2100 may be a printed circuit board. The package substrate 2100 may include a package substrate body portion 2120, package upper pads 2130 disposed on an upper surface of the package substrate body portion 2120, lower pads 2125 disposed on a lower surface of the package substrate body portion 2120 or exposed through the lower surface, and internal wires 2135 electrically connecting the upper pads 2130 with the lower pads 2125 inside the package substrate body portion 2120. The upper pads 2130 may be electrically connected to the connection structures 2400. The lower pads 2125 may be connected to the wiring patterns 2005 of the main board 2001 of the electronic system 2000 through conductive connectors 2800 as shown in FIG. 20.

In the electronic system according to some embodiments, each of the semiconductor chips 2200 may include the semiconductor memory device described with reference to FIGS. 3 to 14. For example, each of the semiconductor chips 2200 may include a peripheral circuit region PERI and a memory cell region CELL stacked on the peripheral circuit region PERI. Illustratively, the peripheral circuit region PERI may include the peripheral circuit board 200 and the first gate electrode 300, which are described with reference to FIGS. 3 to 9. In detail, each of the semiconductor chips 2200 may include an inner source/drain region 410, an outer source/drain region 420 and a ring portion 310.

In concluding the detailed description, those skilled in the art will appreciate that many variations and modifications may be made to the preferred embodiments without substantially departing from the principles of the present invention. Therefore, the disclosed preferred embodiments of the invention are used in a generic and descriptive sense only and not for purposes of limitation.

What is claimed is:

1. A semiconductor device, comprising:
an active region;
a first source/drain region on the active region;
a first contact electrically connected to the first source/drain region;
a second source/drain region spaced apart from the first source/drain region, on the active region;
a first gate electrode on the active region, said first gate electrode including a first ring portion that surrounds the first contact; and
a second contact, which extends outside the first ring portion relative to the first contact, and is electrically connected to the second source/drain region.

2. The semiconductor device of claim 1,
wherein the active region is defined by a device isolation layer, and includes: (i) a central active pattern extended in a first direction, and (ii) a plurality of branch active patterns, which extend from the central active pattern in a second direction that crosses the first direction, and are spaced apart from each other in the first direction;
wherein the device isolation layer extends in the second direction, and between the plurality of branch active patterns; and
wherein the first source/drain region and the first contact are disposed on the central active pattern.

3. The semiconductor device of claim 2, wherein the second source/drain region and the second contact are disposed on the central active pattern.

4. The semiconductor device of claim 2, wherein the second source/drain region and the second contact are disposed on the plurality of branch active patterns.

5. The semiconductor device of claim 2,
wherein the first gate electrode further includes an extension portion, which is connected to the first ring portion and extends in the second direction; and
wherein the extension portion extends between the plurality of branch active patterns, overlaps the device isolation layer, and overlaps the second contact in the first direction.

6. The semiconductor device of claim 2, further comprising a second gate electrode, which extends in the first direction, is spaced apart from the first gate electrode in the second direction, and crosses the plurality of branch active patterns.

7. The semiconductor device of claim 1, further comprising:
a third source/drain region, which is spaced apart from the first source/drain region and the second source/drain region, and is disposed on the active region; and
a third contact on the third source/drain region;
wherein the third contact extends external to the first ring portion; and
wherein the first gate electrode further includes an extension portion, which is connected to the first ring portion, and extends between the second contact and the third contact.

8. The semiconductor device of claim 1, wherein the first ring portion has a closed ring shape that surrounds the first contact.

9. The semiconductor device of claim 1, further comprising:
a fourth source/drain region disposed on the active region; and
a fourth contact on the fourth source/drain region;
wherein the fourth contact extends outside the first ring portion; and
wherein the first contact, the second contact and the fourth contact are arranged in a zigzag layout pattern.

10. The semiconductor device of claim 1, further comprising:
a fifth source/drain region disposed on the active region; and
a fifth contact extending on the fifth source/drain region;
wherein the first gate electrode further includes a second ring portion, which extends on the active region and surrounds the fifth contact; and
wherein the first ring portion and the second ring portion are electrically connected to each other.

11. The semiconductor device of claim 1, wherein the first ring portion has a rhombus layout shape.

12. A semiconductor device, comprising:
a first active pattern extending in a first direction across a substrate;
a second active pattern extending in the first direction, and adjacent the first active pattern in a second direction crossing the first direction;
a device isolation layer extending in the first direction, and adjacent to the first active pattern in the second direction, and adjacent to the second active pattern in the first direction;
a first source/drain region disposed on the first active pattern;
a second source/drain region disposed on the first active pattern and spaced apart from the first source/drain region in the first direction;
a third source/drain region disposed on the second active pattern and spaced apart from the first source/drain region and the second source/drain region;
a first contact on the first source/drain region;
a second contact on the second source/drain region;
a third contact on the third source/drain region; and
a first gate electrode disposed over the first active pattern and the second active pattern, including a first ring portion surrounding the third contact;
wherein the first source/drain region and the second source/drain region are disposed outside the first ring portion; and
wherein the third contact is spaced apart from the first contact in a third direction crossing the first direction and the second direction, and is spaced apart from the second contact in a fourth direction crossing the first direction, the second direction and the third direction.

13. The semiconductor device of claim 12, wherein the first active pattern and the second active pattern are connected to each other; and wherein a first length in which the first active pattern is extended in the first direction is longer than a second length in which the second active pattern is extended in the first direction.

14. The semiconductor device of claim 12, further comprising:
a second gate electrode spaced apart from the first gate electrode in the first direction, and extending in the second direction; and
wherein the second gate electrode crosses the first active pattern and the device isolation layer and does not overlap the second active pattern.

15. The semiconductor device of claim 12, wherein the first gate electrode further includes an extension portion extended from the first ring portion; and wherein the extension portion extends in the first direction and over the second active pattern and the device isolation layer.

16. The semiconductor device of claim 15, wherein the first contact and the second contact do not overlap the device isolation layer, but overlap the extension portion in the second direction.

17. The semiconductor device of claim 15, wherein the first contact and the second contact overlap the device isolation layer and the extension portion in the second direction.

18. The semiconductor device of claim 15, further comprising:
a third active pattern extending adjacent to the second active pattern in the second direction and extending in the first direction;
a fourth source/drain region disposed on the third active pattern; and
a fourth contact extending on the fourth source/drain region;
wherein the second active pattern is disposed between the first active pattern and the third active pattern in the second direction;
wherein the fourth contact is spaced apart from the first contact in the second direction and is spaced apart from the third contact in the fourth direction; and
wherein the extension portion extends between the first contact and the fourth contact.

19. The semiconductor device of claim 12, further comprising:
a fourth active pattern adjacent to the first active pattern in the second direction and extended in the first direction;
a fifth source/drain region disposed on the fourth active pattern; and
a fifth contact on the fifth source/drain region;
wherein the first gate electrode further includes a second ring portion surrounding the fifth contact;
wherein the first ring portion and the second ring portion are connected to each other;
wherein the first gate electrode has a first width in the second direction between the third contact and the fifth contact and has a second width in the third direction between the first contact and the third contact; and
wherein the first width is greater than the second width.

20. A semiconductor device, comprising:
a cell region including a plurality of memory cells;
a plurality of bit lines connected to the plurality of memory cells; and
a peripheral region including a page buffer connected to the plurality of bit lines;
wherein the page buffer includes:
an active pattern;
a first source/drain region disposed on the active pattern;
a second source/drain region spaced apart from the first source/drain region in a first direction and disposed on the active pattern;
a third source/drain region spaced apart from the first source/drain region in a second direction crossing the first direction and disposed on the active pattern;
a fourth source/drain region spaced apart from the first source/drain region in a third direction crossing the first direction and the second direction and disposed on the active pattern;
a first contact on the first source/drain region;
a second contact on the second source/drain region;
a third contact on the third source/drain region;
a fourth contact on the fourth source/drain region; and
a first gate electrode disposed on the active pattern, including a ring portion surrounding the fourth contact;
wherein the first source/drain region, the second source/drain region, the third source/drain region, the first contact, the second contact and the third contact are disposed outside the ring portion; and
wherein the first gate electrode further includes an extension portion extended between the first contact and the second contact.
